(19) United States
(12) Patent Application Publication
(10) Pub. No.: US 2025/0037486 A1
(43) Pub. Date: Jan. 30, 2025

(54) METHOD OF GENERATING DEFECT CLASSIFICATION MODEL

(71) Applicant: SAMSUNG ELECTRONICS CO., LTD., Suwon-si (KR)

(72) Inventors: Jinwoo LEE, Suwon-si (KR); Bumjoo LEE, Suwon-si (KR); Jongcheon SUN, Suwon-si (KR); Suyoung LEE, Suwon-si (KR); Hyeongcheol LEE, Suwon-si (KR)

(73) Assignee: SAMSUNG ELECTRONICS CO., LTD., Suwon-si (KR)

(21) Appl. No.: 18/668,890

(22) Filed: May 20, 2024

(30) Foreign Application Priority Data
Jul. 25, 2023 (KR) 10-2023-0097037

(51) Int. Cl. G06V 20/69; G06T 7/00; G06V 10/764

(52) U.S. Cl. CPC G06V 20/698; G06T 7/001; G06V 10/764; G06T 2207/10056; G06T 2207/30148

(57) ABSTRACT

A method of generating a defect classification model includes preparing a sample wafer that has undergone at least one unit of a manufacturing process, capturing, using an electronic device, a plurality of primary images of different locations of the sample wafer, obtaining a plurality of secondary images based on the capturing of the plurality of primary images, detecting a plurality of defect images including a defect from among the plurality of primary images and the plurality of secondary images, classifying and labeling at least one of the plurality of defect images as defect data, and generating an automatic defect classification model based on the defect data.

### CROSS-REFERENCE TO RELATED APPLICATIONS

This application claims benefit of priority under 35 U.S.C. § 119 to Korean Patent Application No. 10-2023-0097037, filed on Jul. 25, 2023, in the Korean Intellectual Property Office, the disclosure of which is incorporated by reference herein in its entirety.

### BACKGROUND

### 1. Field

The present disclosure relates generally to defect classification models, and more particularly, to a method of generating an automatic defect classification model.

### 2. Description of Related Art

As the electronic industry advances, there may be increasing demands for semiconductor devices capable of performing high-speed operations and/or having mass storage capacities. In order to meet these demands, the structural complexity and/or integration density of the semiconductor devices may be increased. As the integration density of semiconductor devices increases, the ability to control defects that may occur in substrates of the semiconductor devices may increase in importance. For example, defect classification may be performed to control defects that may occur in the substrates.

There exists a need for further improvement in defect classification technology, as the need for increasing structural complexity and/or integration density of semiconductor devices may be constrained by the ability to control defects that may occur in substrates. Thus, automatic defect classification that may provide for increases in process efficiency and/or device reliability may be desired. These improvements may also be applicable to other technologies such as, but not limited to, semiconductor devices.

### SUMMARY

One or more example embodiments of the present disclosure provide a method of generating a defect classification model, which may be continuously used even when process conditions change, by using a plurality of images obtained from a single sample wafer.

According to an aspect of the present disclosure, a method of generating a defect classification model includes preparing a sample wafer that has undergone at least one unit of a manufacturing process, capturing, using an electronic device, a plurality of primary images of different locations of the sample wafer, obtaining a plurality of secondary images based on the capturing of the plurality of primary images, detecting a plurality of defect images including a defect from among the plurality of primary images and the plurality of secondary images, classifying and labeling at least one of the plurality of defect images as defect data, and generating an automatic defect classification model based on the defect data.

According to an aspect of the present disclosure, a method of generating a defect classification model includes preparing a sample wafer that has undergone at least one unit of a manufacturing process, capturing, using an electronic device, a plurality of primary images of different locations of the sample wafer, detecting a plurality of defect images including a defect from among the plurality of primary images, classifying and labeling at least one of the plurality of defect images as defect data, obtaining a plurality of secondary images based on the plurality of defect images, the plurality of secondary images including the defect data, and generating an automatic defect classification model based on the defect data.

According to an aspect of the present disclosure, a method of generating a defect classification model includes preparing a sample wafer that has undergone at least one unit of a manufacturing process, capturing, using an electronic microscope, a plurality of primary images of different locations of the sample wafer, obtaining a plurality of secondary images by changing at least one of a brightness, a color contrast, a pixel size, and a shape of the plurality of primary images, detecting a plurality of defect images by performing data processing on the plurality of primary images and the plurality of secondary images, classifying and labeling at least one of the plurality of defect images as defect data, and generating an automatic defect classification model by performing machine learning based on the defect data.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a diagram illustrating a semiconductor manufacturing process including a defect detection process, according to an embodiment;

FIG. 2 is a flowchart of a method of generating a defect classification model, according to an embodiment;

FIGS. 3A to 3F are diagrams illustrating a method of generating a defect classification model, according to an embodiment;

FIGS. 4A and 4B are flowcharts of methods of generating a defect classification model, according to embodiments;

FIG. 5 is a flowchart of a method of generating a defect classification model, according to an embodiment; and

FIGS. 6A to 6C are diagrams illustrating a method of generating a defect classification model, according to an embodiment.

### DETAILED DESCRIPTION OF THE EMBODIMENTS

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

The terms “first,” “second,” third” may be used to described various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

As used herein, each of the terms “Al”, “Cu”, “GaAs”, “InP”, “SiO”, “SiN”, “SiON”, “TiN”, and the like may refer to a material made of elements included in each of the terms and is not a chemical formula representing a stoichiometric relationship

Hereinafter, various embodiments of the present disclosure are described with reference to the accompanying drawings.

As used herein, the term “defects” may refer to any anomalies that may be found in a substrate.

The term “substrate” may refer to a substrate that may include a semiconductor and/or a non-semiconductor material. Examples of a semiconductor and/or a non-semiconductor material may include, but not be limited to, monocrystalline silicon, gallium arsenide (GaAs), indium phosphide (InP), and the like.

As used herein, a substrate may also be referred to as a wafer. A wafer may refer to a substantially pure silicon substrate. The wafer may include one or more layers formed on the substantially pure silicon substrate. For example, layers on the substantially pure silicon substrate may include insulating paintings, insulating materials, conductive materials, and the like. Insulating paintings may include materials that may be patterned by photolithography, electron-beam lithography, X-ray lithography, and the like. Examples of insulating materials may include, but not be limited to, silicon oxide (SiO), silicon nitride (SiN), silicon oxynitride (SiON), and titanium nitride (TiN).

Examples of conductive materials may include, but not be limited to, aluminum (Al), polysilicon, and copper (Cu).

One or more layers on a wafer may or may not be patterned. For example, a wafer may include a plurality of dies having repetitive pattern characteristics. The forming and/or processing of layers of these materials may need to be performed to complete manufacture of semiconductor devices. Such a wafer may include a substrate with no layers of a complete semiconductor device and/or a substrate with all layers of a complete semiconductor device. A micro-electromechanical system (MEMS) device and other similar devices may also be formed on a wafer as described herein.

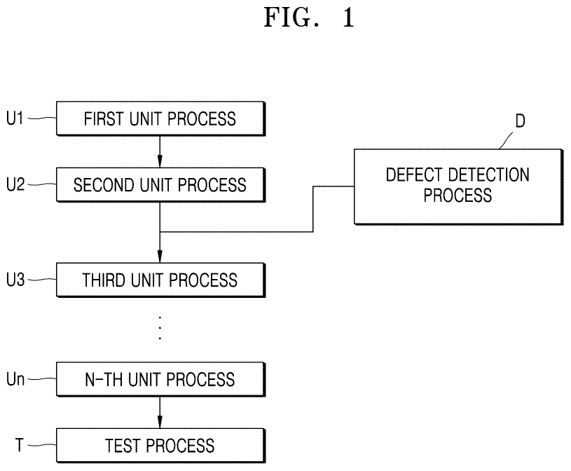

FIG. 1 is a diagram illustrating a semiconductor manufacturing process including a defect detection process, according to an embodiment.

Referring to FIG. 1, the semiconductor manufacturing process may include a plurality of unit processes (e.g., a first unit process U1, a second unit process U2, a third unit process U3, to an N-th unit process Un, where n is a positive integer greater than zero (0)), at least one defect detection process D, and a test process T.

Each of the plurality of first to N-th unit processes U1 to Un may correspond to one of unit processes required to manufacture a semiconductor device. For example, each of the plurality of first to N-th unit processes U1 to Un may correspond to one of various unit processes, such as, but not limited to, a shallow trench isolation (STI) process, an active layer forming process, an ion-implantation process, a gate layer forming process, a circuit pattern forming process, and the like.

After the plurality of first to N-th unit processes U1 to Un are completed, the test process T may be performed to test the electrical characteristics of a substrate that has undergone the plurality of first to N-th unit processes U1 to Un. For example, the test process T may include, but not be limited to, an electrical die sorting (EDS) process, which is performed between a fabrication process and an assembly process to test the electrical characteristics of semiconductor devices formed on the substrate.

The EDS process may refer to a process of applying an electrical signal to pads formed around each of the semiconductor devices on the substrate and determining electrical failure of each semiconductor device according to a signal output in response to the electrical signal.

After at least one of the plurality of first to N-th unit processes U1 to Un is completed, the defect detection process D may be performed.

Although FIG. 1 depicts the defect detection process D being performed only after the second unit process U2 and before the third unit process U3, the present disclosure is not limited thereto. For example, the defect detection process D may be performed whenever each of the plurality of first to N-th unit processes U1 to Un is completed.

For convenience of description, a case in which the defect detection process D is performed after the second unit process U2 and before the third unit process U3 is described as an example.

The defect detection process D may be performed to detect a defect in a substrate that has undergone the second unit process U2. The defect detection process D may be performed by an optical inspection device using a laser, ultraviolet (UV) rays, visible light, and the like. Defects occurring in a substrate that has undergone the second unit process U2 may be detected through the defect detection process D.

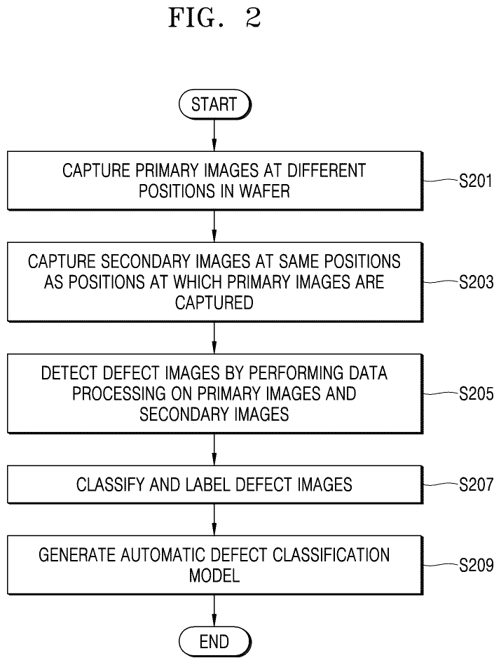

The defect detection process D may refer to a process of finding defects in a substrate by using an automatic defect classification model, as described below. A method of generating an automatic defect classification model is described with reference to FIGS. 2 to 6C.

According to the related art, automatic defect classification may include obtaining an image by using an electron microscope and automatically classifying and counting defects. This automatic defect classification may correspond to a technique of obtaining image data, labeling the image data, and generating a defect classification model. However, the related defect classification model generated using these techniques may not be able to detect defects when a gray level and/or critical dimension (CD) of an image changes due to a change in process conditions. Thus, there is a need for improvements in the generation of defect classification models.

According to an embodiment, a plurality of images may be obtained from a single initial wafer under various conditions, and an automatic defect classification model (hereinafter, referred to as a defect classification model) may continue to be used even when process conditions change. A method of obtaining a plurality of images to generate a defect classification model is described below.

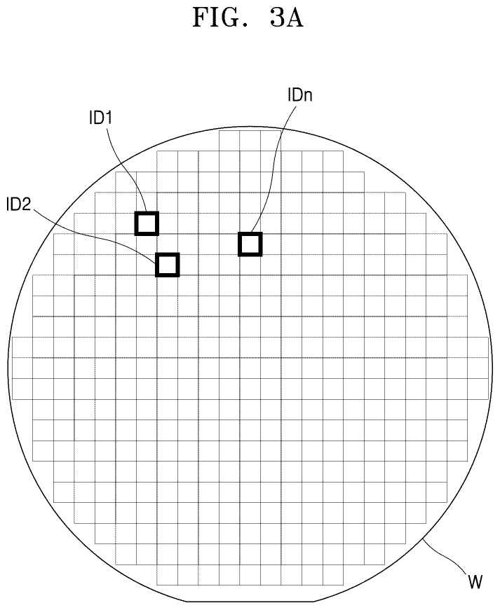

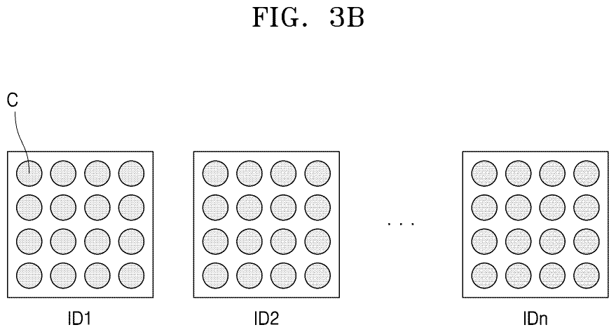

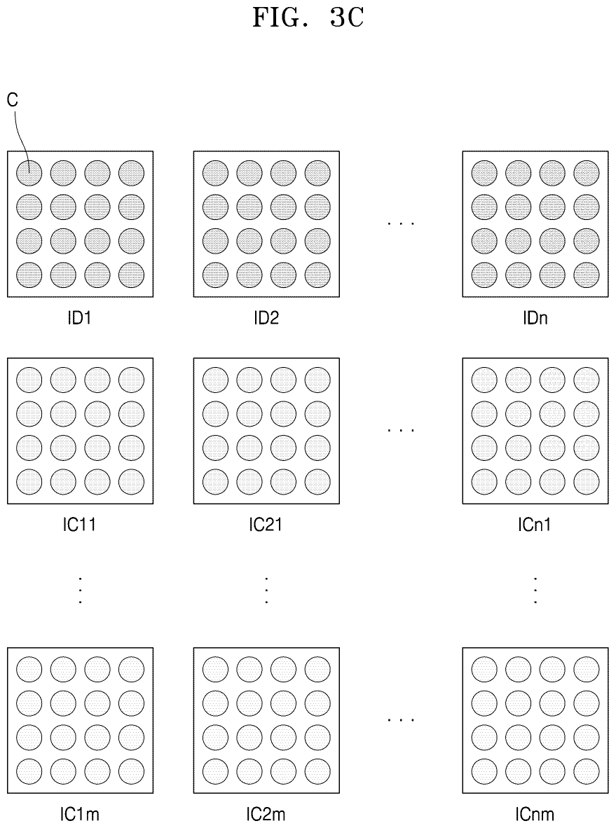

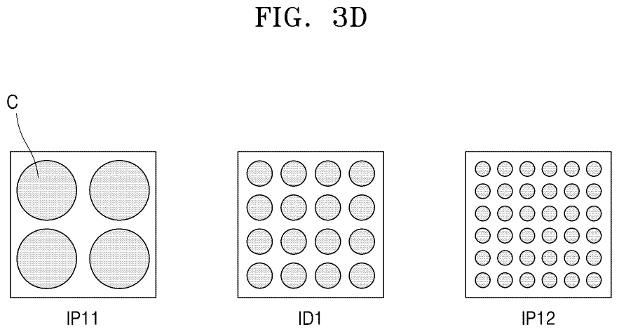

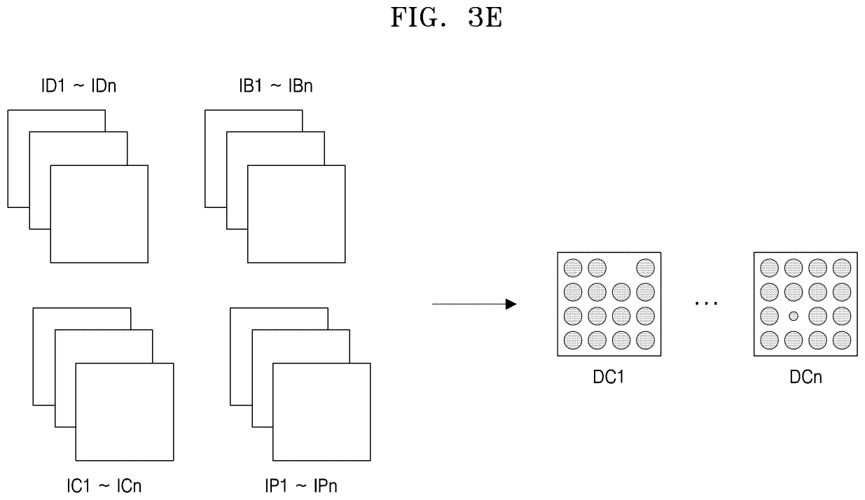

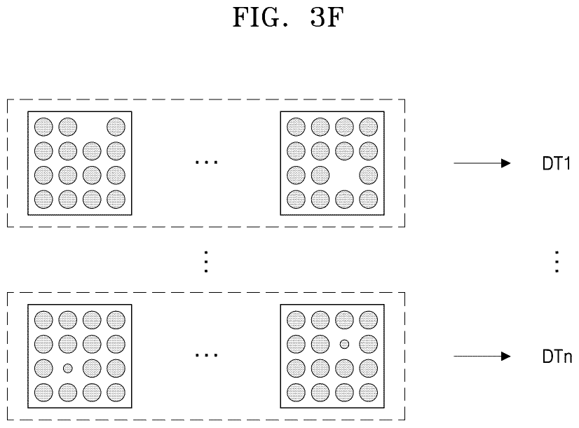

FIG. 2 is a flowchart of a method of generating a defect classification model, according to an embodiment. FIGS. 3A to 3F are diagrams illustrating a method of generating a defect classification model, according to an embodiment.

Referring to FIGS. 2, 3A, and 3B, a method of generating a defect classification model may include capturing a plurality of primary images (e.g., first primary image ID1, second primary image ID2, to n-th primary image IDn) at different positions (locations) in a sample wafer W by using an electronic device in operation S201.

FIG. 3A is a schematic diagram of a stage of capturing the plurality of primary images ID1 to IDn at different positions in the sample wafer W. FIG. 3B is a schematic diagram illustrating the plurality of primary images ID1 to IDn captured at different positions in the sample wafer W.

In some embodiments, the sample wafer W may have undergone at least one unit process. For example, the sample wafer W may have undergone a process of forming a contact C. However, the present disclosure is not limited thereto. The sample wafer W may have undergone various unit processes, such as, but not limited to, an STI process, an active layer forming process, an ion-implantation process, a gate layer forming process, a circuit pattern forming process, and the like.

According to an embodiment, the electronic device may include a scanning electron microscope (SEM) and/or a transmission electron microscope (TEM). However, the present disclosure is not limited thereto. That is, the electronic device may include a device that captures an image of the surface of the sample wafer W by using UV light, deep UV (DUV) light, extreme UV (EUV) light, and/or an electron-beam (e-beam).

The plurality of primary images ID1 to IDn may be captured at different positions (locations). Each of the plurality of primary images ID1 to IDn may be captured to include one die. Alternatively or additionally, each of the plurality of primary images ID1 to IDn may be captured to include a portion of a die. In some embodiments, each of the plurality of primary images ID1 to IDn may be captured to include at least two dies.

Referring to FIGS. 2 and 3C, the method of generating a defect classification model may include obtaining a plurality of secondary images (e.g., first secondary image IC11 to nm-th secondary image ICnm, where n and m are positive integers greater than zero (0)) based on an operation of capturing the plurality of primary images ID1 to IDn. That is, the method may include capturing the plurality of secondary images IC11 to ICnm at the same and/or substantially similar positions (locations) in the sample wafer W as the positions (locations) at which the plurality of primary images ID1 to IDn are captured in operation S203.

According to an embodiment, the plurality of secondary images IC11 to ICnm may be obtained by changing the condition (or recipe) of the electronic device and shooting the sample wafer W. For example, the plurality of secondary images IC11 to ICnm may be obtained by changing a parameter of the electronic device.

According to an embodiment, the plurality of secondary images IC11 to ICnm may have different color contrast than the plurality of primary images ID1 to IDn. For example, the plurality of secondary images IC11 to ICnm may be obtained by changing the color contrast of the electronic device. However, the present disclosure is not limited thereto. For example, the plurality of secondary images IC11 to ICnm may have different brightness and sizes than the plurality of primary images ID1 to IDn.

Referring to FIG. 3C, the plurality of secondary images IC11 to ICnm may include first color contrast-changed images IC11 to ICn1 to m-th color contrast-changed images IC1m to ICnm.

The first color contrast-changed images IC11 to ICn1 may have a different color contrast than the color contrast of the plurality of primary images ID1 to IDn. Alternatively or additionally, the m-th color contrast-changed images IC1m to ICnm may have another different color contrast than the color contrast of the plurality of primary images ID1 to IDn and the color contrast of the first color contrast-changed images IC11 to ICn1. For example, the first color contrast-changed images IC11 to ICn1 may have a lower color contrast when compared to the color contrast of the plurality of primary images ID1 to IDn. As another example, the m-th color contrast-changed images IC1m to ICnm may have lower color contrast than the color contrast of the plurality of primary images ID1 to IDn and the color contrast of the first color contrast-changed images IC11 to ICn1.

Although FIG. 3C shows only the first color contrast-changed images IC11 to ICn1 to the m-th color contrast-changed images IC1m to ICnm, the present disclosure is not limited thereto. For example, the secondary images IC11 to ICnm may include a plurality of brightness-changed images and a plurality of size-changed images. The brightness-changed images may be captured at the same and/or substantially similar positions (locations) in the sample wafer W as the positions (locations) at which the plurality of primary images ID1 to IDn are captured but at different brightness of the electronic device than the brightness at which the plurality of primary images ID1 to IDn are captured. The size-changed images may be captured at the same and/or substantially similar positions (locations) in the sample wafer W as the positions (locations) at which the plurality of primary images ID1 to IDn are captured, but the size-changed images may be captured at different pixel sizes of the electronic device than the pixel sizes at which the plurality of primary images ID1 to IDn are captured.

Referring to FIG. 3D, the method of generating a defect classification model may include obtaining a plurality of size-changed images (e.g., a first changed image IP11 and a second size-changed image IP12), based on the plurality of primary images ID1 to IDn.

According to an embodiment, the first size-changed image IP11 may be captured by reducing the pixel size of the electronic device. For example, the first size-changed image IP11 may be obtained by enlarging and shooting the primary image ID1. In some embodiments, the first size-changed image IP11 may be captured at the same and/or substantially similar position (location) in the sample wafer W as the position (location) at which the primary image ID1 is captured.

According to an embodiment, the second size-changed image IP12 may be captured by increasing the pixel size of the electronic device. For example, the second size-changed image IP12 may be obtained by reducing and shooting the primary image ID1. In some embodiments, the second size-changed image IP12 may be captured at the same and/or substantially similar position (location) in the sample wafer W as the position (location) at which the primary image ID1 is captured.

Various types of defects may be obtained by obtaining a plurality of size-changed images (e.g., first and second size-changed images IP11 and IP12), by changing the pixel size of the electronic device. For example, defect images having an increasing or decreasing CD of the contact C may be obtained.

Referring to FIGS. 2 and 3E, the method of generating a defect classification model may include detecting a plurality of defect images (e.g., first to n-th defect images DC1 to DCn), by performing data processing on the plurality of primary images ID1 to IDn and a plurality of secondary images (e.g., IB1 to IBn, IC1 to ICn, and IP1 to IPn), in operation S205. The defect images DC1 to DCn including a defect may be detected from among the plurality of primary images ID1 to IDn and the plurality of secondary images IB1 to IPn.

In some embodiments, detected defects may include various types of defects occurring during a semiconductor manufacturing process. For example, the defect images DC1 to DCn may include the first defect image DC1 including a defect, in which the contact C is not formed, and the n-th defect image DCn including a CD defect in the contact C. However, the defect images DC1 to DCn are not limited to the defects described above and may include various types of defects, such as, but not limited to, misalignment, scratches, and pattern defects (e.g., a pinch defect in which a pattern is broken and a bridge defect in which adjacent patterns stick to each other), which may occur during a semiconductor manufacturing process.

The plurality of secondary images may include brightness-changed images IB1 to IBn, color contrast-changed images IC1 to ICn, and pixel size-changed images IP1 to IPn. However, the plurality of secondary images are not limited thereto and may further include parameter-changed images compared to the plurality of primary images ID1 to IDn.

The defects in the defect images DC1 to DCn may be detected by performing data processing on all of the plurality of primary images ID1 to IDn and the plurality of secondary images IB1 to IPn. For example, the plurality of primary images ID1 to IDn may be compared with the plurality of secondary images IB1 to IPn, and images determined to have defects may be filtered out and processed as the defect images DC1 to DCn.

The images determined to have defects may be filtered out from the plurality of primary images ID1 to IDn and the plurality of secondary images IB1 to IPn by using a primary algorithm. For example, the defect images DC1 to DCn including anomalies may be detected in the plurality of primary images ID1 to IDn and the plurality of secondary images IB1 to IPn by using a die-to-die algorithm or the like and may be included in a data set.

Referring to FIGS. 2 and 3F, the method of generating a defect classification model may include classifying and labeling the defect images DC1 to DCn in operation S207.

In some embodiments, a user may label the defect images DC1 to DCn in the data set. At least some (a portion) of the defect images DC1 to DCn may be classified and labeled as defect data (e.g., defect type 1 DT1 to defect type n DTn).

For example, from among the defect images DC1 to DCn in the data set, a defect image including a defect, in which the contact C is not formed, may be labeled as defect type 1 DT1. As another example, a defect image including a CD defect in the contact C may be labeled as defect type n DTn from among the defect images DC1 to DCn in the data set. In some embodiments, a defect image including no defect may be labeled as a nuisance from among the defect images DC1 to DCn in the data set. A nuisance may refer to a defect that is not real (e.g., false positive) and/or a defect that a user does not need to worry about (e.g., defect does not meet a desired defect severity threshold). However, the present disclosure is not limited thereto. Various types of defects and a method of classifying and labeling defects may be designed in various ways according to needs and/or design constraints.

The method of generating a defect classification model may include generating an automatic defect classification model in operation S209. The automatic defect classification model may be generated by performing machine learning using the labeled defect data DT1 to DTn as input. That is, at least part (a portion) of the labeled defect data DT1 to DTn may be used as input to generate the automatic defect classification model.

According to an embodiment, when a defect classification model is generated from images obtained under one brightness condition, the defect classification model may provide a decreased (lower) defect capture rate (e.g., about 86.18%) when there is a change in process conditions or the like. For example, the defect classification model may provide a decreased defect capture rate when images having a higher and/or lower brightness are used when compared to the brightness of the images used to generate the defect classification model.

The defect capture rate may be represented as an equation similar to Equation 1.

$$Defect Capture Rate = \frac{Number of detected defects}{Actual number of defects} \times 100 \qquad [ Eq . 1 ]$$

However, when a defect classification model is generated from images obtained under several (e.g., five (5)) brightness conditions, the defect classification model may provide an increased (higher) defect capture rate (e.g., about 97.70%) when there is a change in process conditions or the like.

When a defect classification model is generated from images obtained under one pixel size condition, the resulting defect classification model may provide a decreased defect capture rate (e.g., about 82.90%) when there is a change in process conditions or the like. For example, the defect capture rate provided by the defect classification model may decrease in images having a larger and/or smaller pixel size when compared to the pixel size of the images used to generate the defect classification model. However, when a defect classification model is generated from images having several (e.g., five (5)) pixel size conditions, the defect classification model may provide an increased defect capture rate (e.g., about 98.73%) when there is a change in process conditions or the like.

According to an embodiment, the defect capture rate may be increased by generating a defect classification model with a plurality of images obtained under different conditions. That is, when the images are obtained under different conditions of one sample wafer W and used to generate the defect classification model, the defect classification model may continue to be used when there is a change in process conditions.

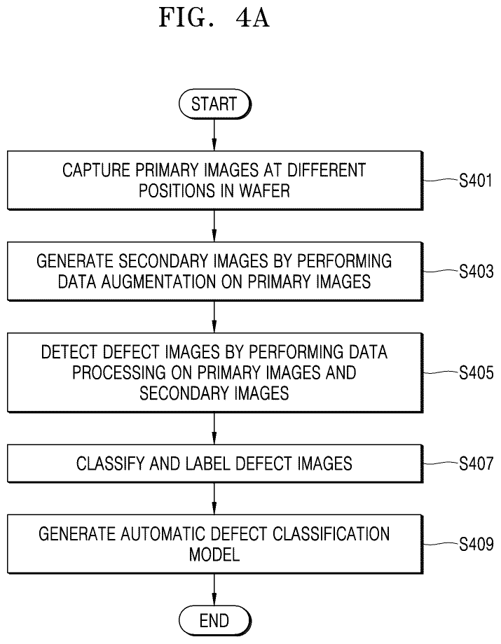

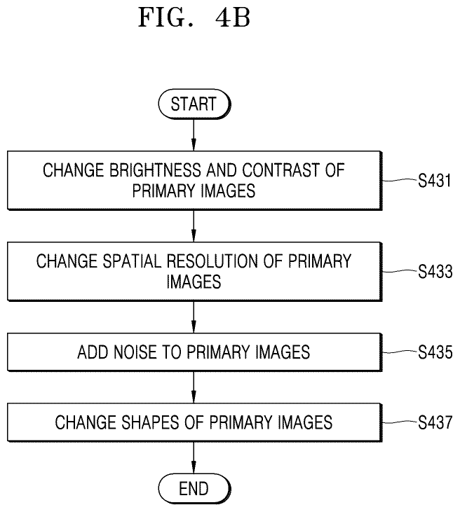

FIGS. 4A and 4B are flowcharts of methods of generating a defect classification model, according to embodiments. FIG. 4A is a flowchart of a method of generating a defect classification model and FIG. 4B is a flowchart of data augmentation in FIG. 4A, according to embodiments. The methods described with reference to FIGS. 4A and 4B may include and/or may be similar in many respects to the methods described above with reference to FIGS. 2 to 3E, and may include additional features not mentioned above. Consequently, repeated descriptions of the methods of FIGS. 4A and 4B described above with reference to FIGS. 2 to 3E may be omitted for the sake of brevity.

Referring to FIGS. 3A, 3B, and 4A, the method of generating a defect classification model may include capturing the plurality of primary images ID1 to IDn at different positions (locations) in the sample wafer W by using an electronic device in operation S401.

In some embodiments, the sample wafer W may have undergone at least one unit process. For example, the sample wafer W may have undergone a process of forming a contact C. However, the present disclosure is not limited thereto. For example, the sample wafer W may have undergone various unit processes, such as, but not limited to, an STI process, an active layer forming process, an ion-implantation process, a gate layer forming process, a circuit pattern forming process, and the like.

According to an embodiment, the electronic device may include an SEM and/or a TEM. However, the present disclosure is not limited thereto. For example, the electronic device may include a device that captures an image of the surface of the sample wafer W by using UV light, DUV light, EUV light, or an e-beam.

The plurality of primary images ID1 to IDn may be captured at different positions (locations). Each of the plurality of primary images ID1 to IDn may be captured to include one die. Alternatively or additionally, each of the plurality of primary images ID1 to IDn may be captured to include a portion of a die. In some embodiments, each of the plurality of primary images ID1 to IDn may be captured to include at least two dies.

Referring to FIGS. 3E, 4A, and 4B, the method of generating a defect classification model may include obtaining a plurality of secondary images IB1 to IPn based on an operation of capturing the plurality of primary images ID1 to IDn. For example, the method may include generating the plurality of secondary images IB1 to IPn by way of data augmentation using the plurality of primary images ID1 to IDn in operation S403.

According to an embodiment, by performing data augmentation on the plurality of primary images ID1 to IDn, the plurality of primary images ID1 to IDn may be converted such that the plurality of secondary images IB1 to IPn may be obtained. For example, the plurality of secondary images IB1 to IPn may be obtained by changing at least one of the brightness, color contrast, and spatial resolution of the plurality of primary images ID1 to IDn.

Referring to FIG. 4B, the data augmentation may include changing the brightness and color contrast (e.g., contrast) of the plurality of primary images ID1 to IDn in operation S431. For example, the plurality of secondary images generated by the data augmentation may include the brightness-changed images IB1 to IBn (as shown in FIG. 3E) having different brightness levels than the plurality of primary images ID1 to IDn. The plurality of secondary images generated by the data augmentation may also include the color contrast-changed images IC1 to ICn (as shown in FIG. 3E) having a different color contrast than the plurality of primary images ID1 to IDn.

When the brightness-changed images IB1 to IBn and the color contrast-changed images IC1 to ICn are obtained by changing the brightness and color contrast of the plurality of primary images ID1 to IDn, various types of defects may be obtained. For example, when a gray level changes due to a change in process conditions, a defect may be detected by using a single defect classification model of the present disclosure.

According to an embodiment, the data augmentation may include changing the spatial resolution of the plurality of primary images ID1 to IDn in operation S433. For example, the plurality of secondary images generated by the data augmentation may include the pixel size-changed images IP1 to IPn (as shown in FIG. 3E) having different pixel sizes than the plurality of primary images ID1 to IDn.

When the pixel size-changed images IP1 to IPn are obtained by changing the spatial resolution of the plurality of primary images ID1 to IDn, various types of defects may be obtained. For example, when the CD of the contact C changes, a defect may be detected by using a single defect classification model of the present disclosure.

According to an embodiment, the data augmentation may include adding noise to the plurality of primary images ID1 to IDn in operation S435. The data augmentation may include changing the shapes of the plurality of primary images ID1 to IDn in operation S437. When noise is added to the plurality of primary images ID1 to IDn and/or the shapes of the plurality of primary images ID1 to IDn are changed, images corresponding to various types of defects occurring in processes may be generated. For example, an image, which corresponds to a defect in which the contact C has an oval shape or a defect in which the contact C has a scratch, may be generated.

The order of performing the data augmentation is not limited to that in FIG. 4B and may be designed in various ways according to needs and/or design constraints.

Referring back to FIGS. 3E and 4A, the method of generating a defect classification model may include detecting a plurality of defect images (e.g., the first to n-th defect images DC1 to DCn) by performing data processing on the plurality of primary images ID1 to IDn and a plurality of secondary images IB1 to IPn, in operation S405. The defect images DC1 to DCn including a defect may be detected from among the plurality of primary images ID1 to IDn and the plurality of secondary images IB1 to IPn.

As used herein, defects may include various types of defects occurring during a semiconductor manufacturing process. For example, the defect images DC1 to DCn may include the first defect image DC1 including a defect, in which the contact C is not formed, and the n-th defect image DCn including a CD defect in the contact C. However, the defect images DC1 to DCn are not limited to the defects described above and may include various types of defects, such as, but not limited to, misalignment, scratches, and pattern defects, which may occur during a semiconductor manufacturing process.

The defect images DC1 to DCn may be detected by performing data processing on all of the plurality of primary images ID1 to IDn and the plurality of secondary images IB1 to IPn. The plurality of primary images ID1 to IDn may be compared with the plurality of secondary images IB1 to IPn, and images determined to have defects may be filtered out and processed as the defect images DC1 to DCn.

The images determined to have defects may be filtered out from the plurality of primary images ID1 to IDn and the plurality of secondary images IB1 to IPn by using a primary algorithm. For example, the defect images DC1 to DCn including anomalies may be detected in the plurality of primary images ID1 to IDn and the plurality of secondary images IB1 to IPn by using a die-to-die algorithm or the like and may be included in a data set.

Referring to FIGS. 3F and 4A, the method of generating a defect classification model may include classifying and labeling the defect images DC1 to DCn in operation S407.

In some embodiments, a user may label the defect images DC1 to DCn in the data set. At least some of the defect images DC1 to DCn may be classified and labeled as defect data (e.g., defect type 1 DT1 to defect type n DTn).

For example, from among the defect images DC1 to DCn in the data set, a defect image including a defect, in which the contact C is not formed, may be labeled as defect type 1 DT1. As another example, a defect image including a CD defect in the contact C may be labeled as defect type n DTn from among the defect images DC1 to DCn in the data set. In some embodiments, a defect image including no defect may be labeled as a nuisance from among the defect images DC1 to DCn in the data set. As described above, a nuisance may refer to a defect that is not real (e.g., false positive) and/or a defect that a user does not need to worry about (e.g., defect does not meet a desired defect severity threshold). However, the present disclosure is not limited thereto. Various types of defects and a method of classifying defects may be designed in various ways according to needs and/or design constraints.

Thereafter, the method of generating a defect classification model may include generating an automatic defect classification model in operation S409. The automatic defect classification model may be generated by performing machine learning using the labeled defect data DT1 to DTn as input. That is, at least part (a portion) of the labeled defect data DT1 to DTn may be used to generate the automatic defect classification model.

According to an embodiment, the defect capture rate may be increased by generating an automatic defect classification model based on a plurality of images under different conditions. For example, by generating the plurality of secondary images IB1 to IPn by performing data augmentation on the plurality of primary images ID1 to IDn captured from one sample wafer W, the defect classification model may continue to be used even when there is a change in process conditions.

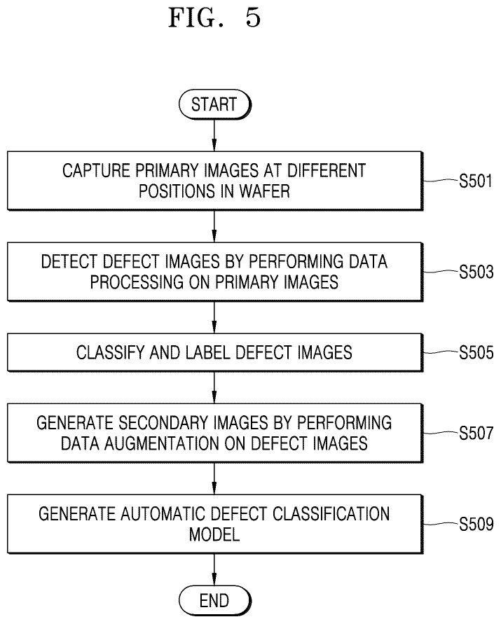

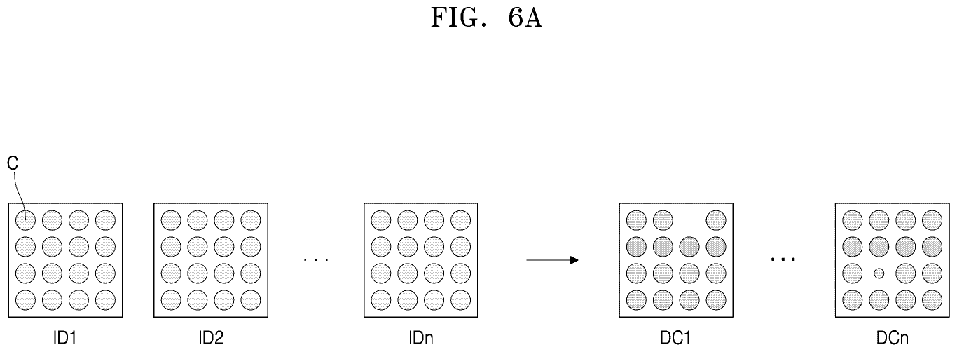

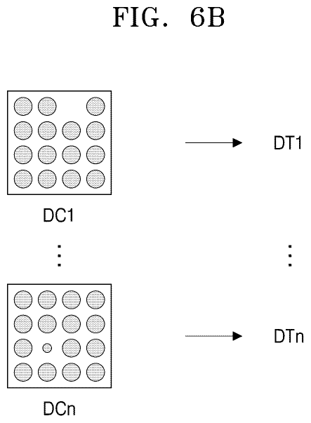

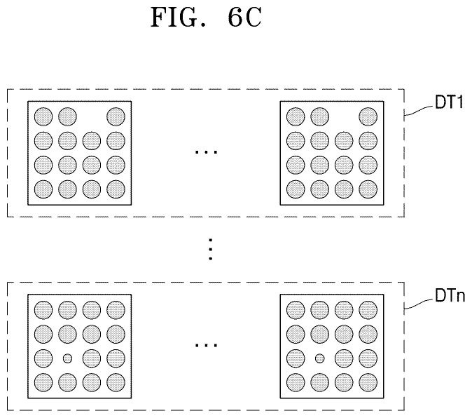

FIG. 5 is a flowchart of a method of generating a defect classification model, according to an embodiment. FIGS. 6A to 6C are diagrams illustrating a method of generating a defect classification model, according to an embodiment. The methods described with reference to FIGS. 5 to 6C may include and/or may be similar in many respects to the methods described above with reference to FIGS. 2 to 4B, and may include additional features not mentioned above. Consequently, repeated descriptions of the methods of FIGS. 5 to 6C described above with reference to FIGS. 2 to 4B may be omitted for the sake of brevity.

Referring to FIGS. 3A, 3B, and 5, the method of generating a defect classification model may include capturing the plurality of primary images ID1 to IDn at different positions (locations) in the sample wafer W by using an electronic device in operation S501.

In some embodiments, the sample wafer W may have undergone at least one unit process. For example, the sample wafer W may have undergone a process of forming a contact C. However, the present disclosure is not limited thereto. For example, the sample wafer W may have undergone various unit processes, such as, but not limited to, an STI process, an active layer forming process, an ion-implantation process, a gate layer forming process, a circuit pattern forming process, and the like.

According to an embodiment, the electronic device may include an SEM and/or a TEM. However, the present disclosure is not limited thereto. For example, the electronic device may include a device that captures an image of the surface of the sample wafer W by using UV light, DUV light, EUV light, or an e-beam.

The plurality of primary images ID1 to IDn may be captured at different positions (locations). Each of the plurality of primary images ID1 to IDn may be captured to include one die. Alternatively or additionally, each of the plurality of primary images ID1 to IDn may be captured to include a portion of a die. In some embodiments, each of the plurality of primary images ID1 to IDn may be captured to include at least two dies.

Referring back to FIGS. 5 and 6A, the method of generating a defect classification model may include detecting a plurality of defect images (e.g., the first to n-th defect images DC1 to DCn) by performing data processing on the plurality of primary images ID1 to IDn in operation S503. The defect images DC1 to DCn, including a defect, may be detected among the plurality of primary images ID1 to IDn.

As used herein, defects may include various types of defects occurring during a semiconductor manufacturing process. For example, the defect images DC1 to DCn may include the first defect image DC1 including a defect, in which the contact C is not formed, and the n-th defect image DCn including a CD defect in the contact C. However, the defect images DC1 to DCn are not limited to the defects described above and may include various types of defects, such as, but not limited to, misalignment, scratches, and pattern defects, which may occur during a semiconductor manufacturing process.

The defect images DC1 to DCn may be detected by performing data processing on all of the plurality of primary images ID1 to IDn. The plurality of primary images ID1 to IDn may be compared with each other, and images determined to have defects may be filtered out and processed as the defect images DC1 to DCn.

The images determined to have defects may be filtered out from the plurality of primary images ID1 to IDn by using a primary algorithm. For example, the defect images DC1 to DCn including anomalies may be detected in the plurality of primary images ID1 to IDn by using a die-to-die algorithm or the like and may be included in a data set.

Referring to FIGS. 5 and 6B, the method of generating a defect classification model may include classifying and labeling the defect images DC1 to DCn in operation S505.

In some embodiments, a user may label the defect images DC1 to DCn in the data set. At least some (a portion) of the defect images DC1 to DCn may be classified and labeled as defect data (e.g., defect type 1 DT1 to defect type n DTn).

For example, from among the defect images DC1 to DCn in the data set, a defect image including a defect, in which the contact C is not formed, may be labeled as defect type 1 DT1. As another example, a defect image including a CD defect in the contact C may be labeled as defect type n DTn from among the defect images DC1 to DCn in the data set. In some embodiments, a defect image including no defect may be labeled as a nuisance from among the defect images DC1 to DCn in the data set. As described above, a nuisance may refer to a defect that is not real (e.g., false positive) and/or a defect that a user does not need to worry about (e.g., defect does not meet a desired defect severity threshold). However, the present disclosure is not limited thereto. Various types of defects and a method of classifying defects may be designed in various ways according to needs and/or design constraints.

Referring to FIGS. 5 and 6C, the method of generating a defect classification model may include generating a plurality of secondary images by way of data augmentation using the defect images DC1 to DCn in operation S507. The plurality of secondary images may include the labeled defect data described above.

According to an embodiment, by performing data augmentation, the defect images DC1 to DCn may be converted such that a plurality of labeled secondary images may be obtained. For example, the plurality of secondary images may be obtained by changing at least one of the brightness, color contrast, and spatial resolution of the defect images DC1 to DCn.

Similar to the method described with reference to FIGS. 4A and 4B, the data augmentation may include changing the brightness and color contrast of the defect images DC1 to DCn. For example, the plurality of secondary images generated by the data augmentation may include brightness-changed images that have different brightness than the defect images DC1 to DCn. The plurality of secondary images generated by the data augmentation may also include color contrast-changed images that have different color contrast than the defect images DC1 to DCn.

When the brightness-changed images and the color contrast-changed images are obtained by changing the brightness and color contrast of the defect images DC1 to DCn, various types of defects may be obtained. For example, when a gray level changes due to a change in process conditions, a defect may be detected by using a single defect classification model of the present disclosure.

According to an embodiment, the data augmentation may include changing the spatial resolution of the defect images DC1 to DCn. For example, the plurality of secondary images generated by the data augmentation may include pixel size-changed images that have different pixel sizes than the defect images DC1 to DCn.

When the pixel size-changed images are obtained by changing the spatial resolution of the defect images DC1 to DCn, various types of defects may be obtained. For example, even when the CD of the contact C changes, a defect may be detected by using a single defect classification model of the present disclosure.

According to an embodiment, the data augmentation may include adding noise to the defect images DC1 to DCn. The data augmentation may include changing the shapes of the defect images DC1 to DCn. When noise is added to the defect images DC1 to DCn and/or the shapes of the defect images DC1 to DCn are changed, images corresponding to various types of defects occurring in processes may be generated. For example, an image, which corresponds to a defect in which the contact C has an oval shape and/or a defect in which the contact C has a scratch, may be generated.

The plurality of secondary images obtained by changing the brightness, color contrast, and pixel sizes of the defect images DC1 to DCn through data augmentation may include labeled defect data, similar to the defect images DC1 to DCn.

The method of generating a defect classification model may include generating an automatic defect classification model in operation S509. The automatic defect classification model may be generated by performing machine learning using the labeled defect data DT1 to DTn as input. That is, at least part (a portion) of the labeled defect data DT1 to DTn may be used as input to generate the automatic defect classification model.

According to an embodiment, a defect capture rate may be increased by generating an automatic defect classification model based on a plurality of images having different conditions. Consequently, by detecting the defect images DC1 to DCn based on the plurality of primary images ID1 to IDn captured from one sample wafer W and generating the plurality of secondary images by using data augmentation, the automatic defect classification model may continue to be used even when there is a change in process conditions.

Because data augmentation is performed on the defect images DC1 to DCn, which have been determined to include a defect among the plurality of primary images ID1 to IDn, users may easily use the automatic defect classification model. In addition, when the data augmentation is performed on the defect images DC1 to DCn, the number of pieces of data may decrease, thereby increasing data storage efficiency.

While the present disclosure has been particularly shown and described with reference to embodiments thereof, it is to be understood that various changes in form and details may be made therein without departing from the spirit and scope of the following claims.

What is claimed is:

1. A method of generating a defect classification model, the method comprising:
preparing a sample wafer that has undergone at least one unit of a manufacturing process;
capturing, using an electronic device, a plurality of primary images of different locations of the sample wafer;
obtaining a plurality of secondary images based on the capturing of the plurality of primary images;
detecting a plurality of defect images comprising a defect from among the plurality of primary images and the plurality of secondary images;
classifying and labeling at least one of the plurality of defect images as defect data; and
generating an automatic defect classification model based on the defect data.

2. The method of claim 1, wherein the obtaining of the plurality of secondary images comprises:
changing an image-capturing parameter of the electronic device; and
capturing, using the changed image-capturing parameter, at least one secondary image of the plurality of secondary images.

3. The method of claim 2, wherein the image-capturing parameter comprises at least one of a brightness, a color contrast, and a pixel size of the electronic device.

4. The method of claim 2, wherein the capturing of the at least one secondary image comprises capturing the at least one secondary image of a same location of the sample wafer as a location corresponding to at least one primary image of the plurality of primary images.

5. The method of claim 2, wherein the capturing of the plurality of primary images comprises capturing the plurality of primary images at a first magnification level,
wherein the capturing of the at least one secondary image comprises capturing the at least one secondary image at a second magnification level, and
wherein the second magnification level is different than the first magnification level.

6. The method of claim 1, wherein the obtaining of the plurality of secondary images comprises generating the plurality of secondary images by performing data augmentation on the plurality of primary images.

7. The method of claim 6, wherein the performing of the data augmentation comprises changing at least one of a brightness, a color contrast, and a spatial resolution of the plurality of primary images.

8. The method of claim 7, wherein the performing of the data augmentation further comprises adding noise to the plurality of primary images.

9. The method of claim 7, wherein the performing of the data augmentation further comprises changing a shape of a defect image of the plurality of primary images.

10. The method of claim 1, wherein the detecting of the plurality of defect images comprises detecting the plurality of defect images by performing data processing on the plurality of primary images and the plurality of secondary images.

11. The method of claim 1, wherein the generating of the automatic defect classification model comprises generating the automatic defect classification model by performing machine learning using the defect data as input of the automatic defect classification model.

12. The method of claim 1, wherein the electronic device comprises at least one of a scanning electron microscope (SEM) and a transmission electron microscope (TEM).

13. A method of generating a defect classification model, the method comprising:
preparing a sample wafer that has undergone at least one unit of a manufacturing process;
capturing, using an electronic device, a plurality of primary images of different locations of the sample wafer;
detecting a plurality of defect images comprising a defect from among the plurality of primary images;
classifying and labeling at least one of the plurality of defect images as defect data;
obtaining a plurality of secondary images based on the plurality of defect images, the plurality of secondary images comprising the defect data; and
generating an automatic defect classification model based on the defect data.

14. The method of claim 13, wherein the obtaining of the plurality of secondary images comprises generating the plurality of secondary images by performing data augmentation on the plurality of defect images.

15. The method of claim 14, wherein the performing of the data augmentation comprises changing at least one of a brightness, a color contrast, and a spatial resolution of the plurality of defect images.

16. The method of claim 13, wherein the detecting of the plurality of defect images comprises detecting the plurality of defect images by performing data processing on the plurality of primary images.

17. The method of claim 16, wherein the generating of the automatic defect classification model comprises generating the automatic defect classification model by performing machine learning using a portion of the defect data as input of the automatic defect classification model.

18. A method of generating a defect classification model, the method comprising:
preparing a sample wafer that has undergone at least one unit of a manufacturing process;
capturing, using an electronic microscope, a plurality of primary images of different locations of the sample wafer;
obtaining a plurality of secondary images by changing at least one of a brightness, a color contrast, a pixel size, and a shape of the plurality of primary images;
detecting a plurality of defect images by performing data processing on the plurality of primary images and the plurality of secondary images;
classifying and labeling at least one of the plurality of defect images as defect data; and
generating an automatic defect classification model by performing machine learning based on the defect data.

19. The method of claim 18, wherein the obtaining of the plurality of secondary images comprises:
changing an image-capturing parameter of the electronic microscope; and
capturing, using the changed image-capturing parameter, at least one secondary image of the plurality of secondary images of a same location of the sample wafer as a location corresponding to at least one primary image of the plurality of primary images.

20. The method of claim 18, wherein the obtaining of the plurality of secondary images comprises generating the plurality of secondary images by performing data augmentation on the plurality of primary images.
